(19) United States
(12) Patent Application Publication
(10) Pub. No.: US 2022/0324885 A1
(43) Pub. Date: Oct. 13, 2022

(54) TWIN-MONOMER COMPOSITION AND DIELECTRIC FILM THEREOF

(71) Applicant: BASF SE, Ludwigshafen am Rhein (DE)

(72) Inventors: Szilard CSIHONY, Ludwigshafen am Rhein (DE); Jean-Pierre Berkan LINDNER, Ludwigshafen am Rhein (DE); Daniel LOEFFLER, Ludwigshafen am Rhein (DE); Yeni BURK, Ludwigshafen am Rhein (DE); Ingolf HENNIG, Ludwigshafen am Rhein (DE); Lucas Benjamin HENDERSON, Ludwigshafen am Rhein (DE); Birgit GERKE, Ludwigshafen am Rhein (DE); Rui DE OLIVEIRA, Ludwigshafen am Rhein (DE); Volodymyr BOYKO, Ludwigshafen am Rhein (DE); Frank PIRRUNG, Ludwigshafen am Rhein (DE)

(21) Appl. No.: 17/626,836

(22) PCT Filed: Jul. 3, 2020
(86) PCT No.: PCT/EP2020/068823

§ 371 Date: Jan. 13, 2022

(30) Foreign Application Priority Data
Jul. 18, 2019 (EP) 19186995.7

(51) Int. Cl. C07F 7/04; C08G 61/10; C08K 3/36; H05K 1/03

(52) U.S. Cl. CPC C07F 7/04; C08G 61/10; C08K 3/36; H05K 1/0326; C08G 2261/65; C08G 2261/1424; H05K 1/0298

(57) ABSTRACT

A composition comprising a monomer of the general formula (M1) wherein M is a metal or semimetal of main group 3 or 4 of the periodic table; X^{M1}, X^{M2} are each O; R^{M1}, R^{M2} are the same or different and are each an —CR^{a}R^{b}—Ar—O—R^{c}; Ar is a C₆ to C₃₀ carbocyclic ring system; R^{a}, R^{b} are the same or different and are each H or C₁ to C₆ alkyl; R^{c} is C₁-C₂₂-alkyl, benzyl or phenyl; q according to the valency and charge of M is 0 or 1; X^{M3}, X^{M4} are the same or different and are each O, C₆ to C₁₀ aryl, or —CH₂—; R^{M3}, R^{M4} are the same or different and are each R^{M1}, H, C₁-C₂₂ alkyl, or a polymer selected from a polyalkylene, a polysiloxane, or a polyether.

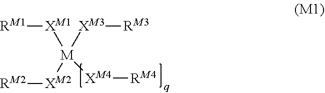

### BACKGROUND OF THE INVENTION

The present invention relates to a composition comprising a monomer containing both inorganic or organometallic and organic moieties with aromatic or heteroaromatic structural units (twin monomer). Furthermore, the present invention relates to the application of such compositions for manufacturing insulating films, prepregs, multilayered printed wiring boards, and semiconductor devices.

In recent years, downsizing and high functionalization of electronic instruments have been advanced. In multilayered printed wiring boards, a buildup layer has been made multilayered, and micro fabrication and high densification of wirings have been required.

Composite materials, i.e. polymer-based composites formed from at least one organic polymer phase and at least one inorganic or organometallic phase, for example an inorganic metal oxide phase, often feature interesting physical, properties, for example mechanical, electrical and/or optical properties, which makes them excellent material as insulating layer with good thermal resistance, electric insulating property.

An established class of compounds useful for manufacturing such build-up layers are epoxy resins as describe e.g. in US 2011/120761 A or US 2014/087152 A. These epoxy resins are usually applied in combination with an inorganic filler.

Interlayer insulating materials in a multilayer printed-wiring board that is formed by stacking conductor circuitry layers and insulating layers alternately, require low dielectric constant and dielectric loss (loss tangent, tan δ). However, dielectric properties of these material class is often insufficient for advanced packaging applications. Especially dielectric properties like the dielectric dissipation factor (also referred to as loss tangent) D_{f} or the dielectric constant Dₖ are often insufficient compared to other materials like polyimides or polybenzoxazoles. Therefore, there is still a need for compounds that fulfill the above-mentioned requirements. The currently used epoxy resin compositions have relative high loss tangent of approx. 0.02. Addition of 40-85% silica lowers the values to around 0.01 of the formed film, but the nature of chemistry does not allow lower loss tangent values.

Spange et al., Angew. Chem. Int. Ed., 46 (2007) 628-632 describe a route to nanocompositions by acid-catalyzed cationic polymerization of tetrafurfuryloxysilane (TFOS) and difurfuryloxydimethylsilane. The polymerization of TFOS under cationic, i.e. acidic, conditions forms a composite material which has a silicon dioxide phase and an organic polymer phase composed of polyfurfuryl alcohol (PFA).

Similar processes for producing nanocomposits by twin polymerization are known from WO 2009/083083, WO 2010/128144, WO 2010/112581, WO 2011/000858, and US 2014/017411 A. These processes relate to the homo- or copolymerization of “twin monomers” like 2,2′-spiro-bis[4H-1,3,2-benzodioxasilin] (BIS) or 2-methyl-2-octadecyl-[4H-1,3,2-benzodioxasilin]. In these twin monomers at least one organic moiety is connected to the central metal or semimetal atom in a bidentate way, i.e. by forming two bonds to the metal or semimetal atom. Furthermore, the known twin-polymer systems based on phenol or phenolic derivatives comprise free OH groups that, similar to epoxy systems, lower dielectric loss of the composite. However, the hydroxy group was essential in the prior art systems to activate the benzyl ring to initiate the cationic polymerization.

WO 09/133082 discloses low-k dielectrics obtainable by twin polymerization. One of the starting materials for the twin polymerization is tetrafurfuryloxysilane (TFOS). However, this starting material is not suitable for film production. The monomer is too reactive, and addition of any acid starts a local polymerization forming inhomogeneous film.

US 2002068173 A1 discloses the compound PhSi(OC₄He)₃ used for manufacturing printed wiring boards.

Additionally, previous systems use either well-defined spiro-compounds that cannot be varied or made from tetraphenoxy derivatives, which requires the addition of a formaldehyde source for polymerization.

It is an object of the present invention to provide a composition and a composite material which no longer exhibits the disadvantages of prior art compositions. In particular, the compounds according to the present invention shall provide a composite material, in particular dielectric films having improved dielectric properties, particularly improved D_{f} and Dₖ. Furthermore, the composition according to the present invention shall be applicable for use in electronic applications, particularly as insulating layer for packaging applications.

### SUMMARY OF THE INVENTION

Surprisingly, it was found that even simple silanes comprising alkoxyaryl substituents may be polymerized without an additional formaldehyde source but simply by using an acidic catalyst in a controlled way to form a useful composite material, in particular a dielectric film.

A first aspect of the present invention relates to a composition comprising a monomer of the general formula M1

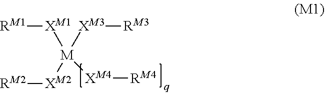

wherein
M is a metal or semimetal of main group 3 or 4 of the periodic table;
X^{M1} X^{M2} are each O;
R^{M1}, R^{M2} are the same or different and are each an —CR^{a}R^{b}—Ar—O—R^{c};
Ar is a C₆ to C₃₀ carbocyclic ring system;
R^{a}, R^{b} are the same or different and are each H or C₁ to C₆ alkyl;
R^{c} is C₁-C₂₂-alkyl, benzyl or phenyl;
q according to the valency and charge of M is 0 or 1;
X^{M3} X^{M4} are the same or different and are each O, C₆ to C₁₀ aryl, or —CH₂—;
R^{M3}, R^{M4} are the same or different and are each R^{M1}, H, C₁-C₂₂ alkyl, or a polymer selected from a polyalkylene, a polysiloxane, or a polyether.

Without to be bound to any theory, it seems that a proper activation of the aryl rings may be achieved by using activating substituents instead of hydroxy groups. In the dielectric film, alkoxy groups contribute much less to dielectric loss than hydroxy groups.

A further advantage of the present invention is that the polymerization can be carried out at relatively low temperature if a catalyst, particularly a Bronsted acid, is added.

Polymerized compositions comprising twin monomers offer with their nanodomains very good connection between organic and inorganic phases. In contrast to the known systems based on phenol or phenolic derivatives with free OH groups the composites according to the present invention show an improved dielectric loss.

Additionally, the twin-monomer system used shows much more flexibility with respect to the selection of the aromatic system and its substituents compared to the prior art systems.

Another aspect of the present invention is a process for producing a dielectric film by applying a composition comprising a compound of formula M1 onto a substrate and polymerizing the monomer of formula M1 in the presence of acidic catalyst at temperature of preferably from 60° C. to 200° C. The advantages of the process according to the invention is the ability to polymerize formula M1 in a thin layer. In this way, it is possible to produce thin layers of the composition which do not have at least some of the disadvantages of the prior art and are especially set apart from the prior art by at least one and preferably more than one or all of the following advantages:
fewer defects within the layer,
improved mechanical stability of the layer,
lower discoloration, if any,
more homogeneous layer thickness,
less inhomogeneity, if any, within the layer,
better adhesion on the coated substrate.

Another aspect of the present invention is the use of a composition as described herein for depositing a dielectric material, particularly a dielectric film, on a circuit substrate, particularly for manufacturing a printed wiring board.

Yet another aspect of the present invention relates to a dielectric film preparable by polymerizing a twin monomer composition as described herein in the presence of an acidic catalyst at temperature of preferably from 60° C. to 200° C., wherein the dielectric layer has a dielectric resistance Dₖ of 3 or below and a loss tangent D_{f} of 0.02 or below, particularly 0.01 or below.

Yet another aspect of the present invention relates to a multilayered printed wiring board, comprising the dielectric film as described herein.

Yet another aspect of the present invention relates to a semiconductor device comprising the multilayered printed wiring board as described herein.

### DETAILED DESCRIPTION OF THE INVENTION

The composition according to the present invention comprises a twin-monomer as described herein, optionally in the presence of other ingredients.

As used herein, “a” or “an” and “at least one” are used synonymously. Ther terms “composition” and “twin-monomer composition” are used herein synonymously.

In a particular embodiment of the present invention the composition essentially consists of, preferably consists of

(a) a twin-monomer

(b) optionally an acid catalyst,

(c) optionally an inorganic filler,

(d) optionally a thermoplastic resin,

(e) optionally a rubber particle, and

(f) optionally a flame retardant.

Essentially consisting of here means that other components may be mixed in the composition of the present invention within a range not adversely affecting the effects of the present invention, particularly do not increase the dielectric constant or dielectric loss tangent. Such other components may be a thickener such as Orben and Bentone; a silicone-based, fluorine-based, or polymer-based defoaming agent or leveling agent; an adhesion imparting agent such as imidazole-based, thiazole-based, triazole-based, and silane-based coupling agents; and a colorant such as phthalocyanine blue, phthalocyanine green, iodine green, disazo yellow, and carbon black. Preferably the content of such other components is 1% by weight or below, particularly 0.1% by weight or below based on the whole composition.

Twin Monomers

The essential part of the composition for forming a dielectric layer or film is a twin monomer of the general formula M1

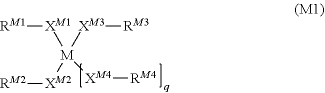

This composition can be polymerized by twin polymerization to form dielectric materials, in particular dielectric layers or films.

The monomer of formula M1 are also referred to herein as “twin monomer” and the resulting polymer is referred to as “twin polymer”.

The monomers of the formula M1 are those in which M is selected from the metals and semimetals of main group 3 (IUPAC group 3), especially B or Al, metals and semimetals of main group 4 of the periodic table (IUPAC group 14), especially Si, Ge, and metals of transition group 4 of the periodic table, especially Ti and Zr. The twin polymerization is especially suitable for polymerization of those monomers of the formula M1 in which M is selected from the semimetals of main group 4 of the periodic table, especially Si, and metals of transition group 4 of the periodic table, especially Ti. The twin polymerization is suitable with particular preference for polymerization of those monomers of the formula M1 in which M at least in a portion of or the entirety of the monomers is essentially or exclusively Si.

Preferred monomers of the formula M1 are those in which q is 1 and M is selected from Si and Ti, and is especially Si.

The monomers of the formula M1 are those in which R^{M1} and R^{M2} are the same or different and are each an —CR^{a}R^{b}—Ar—O—R^{c}. Herein Ar is a C₆ to C₃₀ carbocyclic ring system, R^{a}, R^{b} are the same or different and are each H or C₁ to C₆ alkyl and R^{c} is C₁-C₂₂-alkyl, benzyl or phenyl. Preferably Ar is phenyl or naphthyl, most preferably phenyl.

Preferably R^{a} and R^{b} are the same or different and are each H or C₁ to C₄ alkyl, more preferably H, methyl, ethyl or propyl, most preferably H.

Preferably R^{c} is C₁-C₂₀-alkyl, benzyl or phenyl, more preferably C₁-C₂₀-alkyl, benzyl or phenyl, even more preferably C₁-C₁₂-alkyl or benzyl, even more most preferably methyl, ethyl, 1- or 2-propyl, or n-butyl, iso-butyl or t-butyl.

The monomers of the formula M1 are those in which X^{M3} and X^{M4} are the same or different and are each O, C₆ to C₁₀ aryl, or —CH₂—. Preferably X^{M3} and X^{M4} are O or CH₂.

The monomers of the formula M1 are those in which R^{M3}, R^{M4} are the same or different and are each R^{M1} as defined herein, H, C₁-C₂₂ alkyl, or a polymer selected from polyalkylene, a polysiloxane, or a polyether. Preferably R^{M3}, R^{M4} are R^{M1}, C₁-C₁₈ alkyl or a polymer selected from a polysiloxane or a C₂ to C₄ polyalkylene oxide, more preferably R^{M1}, C₁-C₁₂ alkyl or a polyethylene oxide, a polypropylene oxide or a copolymer of ethylene oxide and propylene oxide, most preferably R^{M1} or C₁ to C₆ alkyl.

Preferably X^{M3}—R^{M3} and X^{M4}—R^{M4} are the same as X^{M1}—R^{M1}.

In a first preferred embodiment the twin monomer has the general formula M2

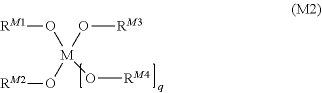

Herein
M is a metal or semimetal, generally a metal or semimetal of main group 3 or 4 or of transition group 4 of the periodic table, preferably B, Al, Si, Ti or Zr, most preferably Si;
R^{M1}, R^{M2} are each an —CR^{a}R^{b}—Ar—O—R^{c};
Ar is a C₆ to C₁₂ aromatic ring and particularly a phenyl ring;
R^{a}, R^{b} are the same or different and are each H or C₁ to C₄ alkyl;
R^{c} is C₁-C₁₂-alkyl, benzyl or phenyl, preferably methyl, ethyl, propyl, or butyl;
q according to the valency and charge of M is 0 or 1;
R^{M3}, R^{M4} are each R^{M1}.

Preferably, the twin monomer has the general formula M2a

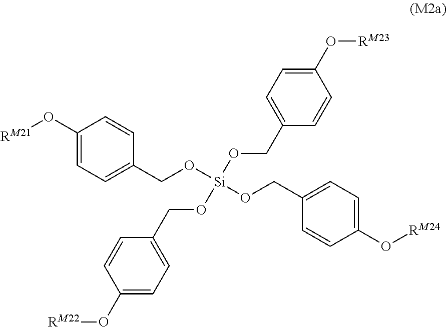

or M2a′

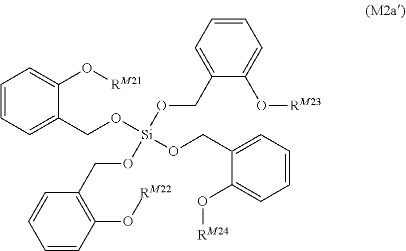

wherein R^{M21}, R^{M22}, R^{M23}, and R^{M24} are the same or different, preferably the same, and each independently selected from C₁ to C₁₈ alkyl, preferably C₁ to C₁₂ alkyl, even more preferably C₁ to C₁₂ alkyl, most preferably methyl, ethyl, propyl or butyl.

In a second preferred embodiment the twin monomer has the general formula M2, wherein
M is a metal or semimetal, generally a metal or semimetal of main group 3 or 4 or of transition group 4 of the periodic table, preferably B, Al, Si, Ti or Zr, most preferably Si;
R^{M1}, R^{M2} are each an —CR^{a}R^{b}—Ar—O—R^{c};
Ar is a C₆ to C₁₂ aromatic ring and particularly a phenyl ring;
R^{a}, R^{b} are the same or different and are each H or C₁ to C₄ alkyl.
R^{c} is C₁-C₁₂-alkyl, benzyl or phenyl, preferably methyl, ethyl, propyl, or butyl;
q according to the valency and charge of M is 0 or 1;
R^{M3}, R^{M4} are the same or different and are each H, C₁-C₂₂ alkyl, or a polymer, preferably a polyalkylene, a polysiloxane, or a polyether.

By using twin-monomers of the second embodiment, less brittle dielectric films may be formed that have an improved dielectric constant Dₖ and loss tangent D_{f}.

Preferably, the twin monomer has the general formula M2b

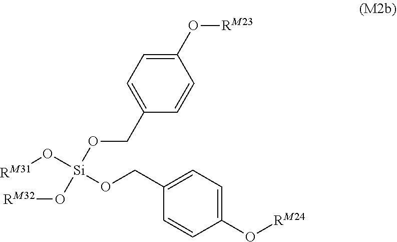

or M2b′

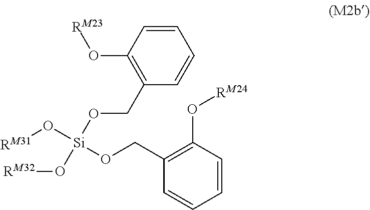

wherein R^{M31}, R^{M32}, R^{M23}, and R^{M24} are each independently selected from methyl, ethyl, propyl or butyl.

In a third preferred embodiment the composition comprises two types of twin monomers of the first and the second embodiments above in combination. Herein, the monomers according to the first and the second embodiment may be used in a mixing ratio of from 5:95 to 95:5 by weight, preferably of from 10:90 to 90:10 by weight, more preferably of from 20:80 to 80:20 by weight, even more preferably of from 25:75 to 75:25 by weight, most preferably of from 30:70 to 70:30 by weight.

By variation of the amounts of monomers of embodiment 1 and embodiment 2 the flexibility and dielectric properties of the dielectric material may be adjusted.

By way of a non-limiting example of tetra-4-methoxybenzyloxysilane, the twin monomers polymerize in the following way:

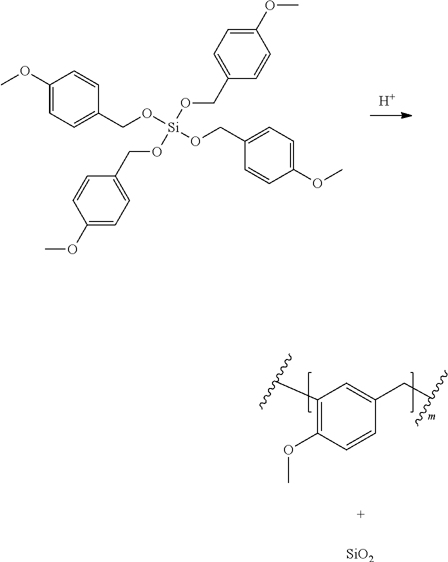

The more monomers of the second embodiment are added the higher the organic (silane) content of the inorganic silica phase will be. This leads to an increased flexibility of the film formed.

Catalyst

The composition according to the present invention comprises or is used in combination with a catalyst since the twin-polymerization is performed in the presence of a catalyst.

Customary catalysts are acids, namely Bronsted acids and Lewis acids, preferably Bronsted acids. The acids are generally used in concentrations of from 0.01 to 10% by weight, preferably of from 0.1 to 5% by weight, most preferably of from 0.5 to 3% by weight, based on the twin-monomers.

In a first embodiment, the catalyst may be added to the composition before or when applying it onto the substrate to form the dielectric layer on the substrate. This means, the acid is either (a) part of the composition, (b) part of a kit to be applied together with the twin-monomer composition when forming the twin-monomer film.

In another embodiment, the catalyst may be applied to the composition after its application onto the substrate to form the dielectric film. This may be realized by vaporizing an acid having a sufficiently high vapor pressure to the dielectric film surface for a time sufficient to cause polymerization of the whole film. Useful acids are methanesulfonic acid, acetic acid, and fluorosulfonic acid, trifluoromethanesulfonic acid and other acids having a sufficiently low boiling point.

In a third embodiment an acid precursor material is added to the composition before or when applying it onto the substrate to form the dielectric layer and afterwards the catalyst, particularly the acid, is formed by decomposition of the precursor material. For example, such precursor materials may be decomposed by heating or by radiation.

Inorganic Filler

The composition preferably comprises an inorganic filler.

The inorganic filler used in the present invention is not particularly limited. Examples thereof may include silica, alumina, barium sulfate, talc, clay, a mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, and calcium zirconate. Among these, silica is preferable. Further, silica such as amorphous silica, pulverized silica, fumed silica, crystalline silica, synthetic silica and hollow silica are preferable, and fumed silica is more preferable. Spherical silica is preferable as the silica. These may be used alone or in combination of two or more kinds thereof.

The average particle diameter of the inorganic filler is not particularly limited. From the viewpoint of forming a fine wiring on an insulating layer, the upper limit of the average particle diameter of the inorganic filler is preferably 5 micrometer or less, more preferably 3 micrometer or less, still more preferably 1 micrometer or less, yet still more preferably 0.7 micrometer or less, particularly preferably 0.5 micrometer or less. On the other hand, the lower limit of the average particle diameter of the inorganic filler is preferably 0.01 micrometer or more, more preferably 0.03 micrometer or more, still more preferably 0.05 micrometer or more, yet still more preferably 0.07 micrometer or more, and particularly preferably 0.1 micrometer or more, from the viewpoint that, when forming a composition varnish from a twin-polymer composition, a reduction of the handleability due to an increase in the viscosity of the varnish can be prevented. The average particle diameter of the inorganic filler can be measured by a laser diffraction and scattering method on the basis of the Mie scattering theory. Specifically, the particle size distribution of the inorganic filler is prepared on the volume basis using a laser diffraction particle size distribution measuring device, and a median diameter thereof can be measured as an average particle diameter. As a measurement sample, there can be preferably used a dispersion in which the inorganic filler is dispersed in water by ultrasonification. As the laser diffraction particle size distribution measuring device, LA-500, 750, and 950 manufactured by Horiba, Ltd., or the like can be used.

Although the content of the inorganic filler varies depending upon characteristics required for the composition, it is preferably from 20 to 85% by weight, more preferably from 30 to 80% by weight, still more preferably from 40 to 75% by weight, and yet still more preferably from 50 to 70% by weight when a content of non-volatile components in the composition is defined as 100% by weight. When the content of the inorganic filler is too small, the thermal expansion coefficient of the dielectric film tends to be high. When the content is too large, there is a tendency that the dielectric film becomes brittle and the peel strength is lowered.

It was surprisingly found that the use of the twin polymers leads to a better compatibility between the inorganic filler and the polymer phase even if the surface of the inorganic filler is not functionalized. In contrast to the twin polymers, the performance of traditional epoxy resins highly depends on the pre-treatment of the inorganic filler.

The method for preparing the composition of the present invention is not particularly limited, and examples thereof may include a method of mixing blending components using a rotary mixer or the like with, if necessary, a solvent or the like.

Other Components

Further additives may be present in the composition according to the present invention as described below.

Binder

The composition may further comprise a binder.

Such binders may particularly be the selected from the following polymeric materials:

Polyethylene oxide (PEO), cellulose, carboxymethyl cellulose, polyvinyl alcohol, polyethylene, polypropylene, polytetrafluorethylene, polyacrylate or polymethacrylate, polyacrylnitrile-methylmethacrylate copolymers, polystyrene, styrene-butadiene copolymers, tetrafluoro-ethylene-hexafluorpropylene copolymers, vinylidene fluoride-hexafluorpropylene copolymers (PVdF-HFP), vinylidene fluoride-tetrafluorethylene copolymers, perfluoralkyl vinylether copolymers, ethylene-tetrafluorethylen copolymers, vinylidenefluoride-chlortrifluoroethylene copolymers, ethylene-chlorfluorethylene copolymers, ethylene-acrylic acid copolymers, if required, at least partially neutralized with alkaline metal salts or ammonia, ethylene-methacrylic acid copolymers, if required, at least partially neutralized with alkaline metal salts or ammonia, ethylene-(meth)acrylic acid ester copolymers, polyimides and polyisobutene.

The binders are selected based on the properties of the solvent required for its preparation. The binder may be used in an amount of from 1 to 10% by weight (based on the whole dielectic composition material). Preferably 2 bis 8% by weight, particularly 3 bis 7% by weight may be used.

Polyacrylate and Polymethacrylate

In its most generic definition, the poly(meth)acrylates are defined as follows:

The polymers of alkyl esters of (meth)acrylic acid are preferably those comprising 0-100% by weight of methyl(meth)acrylate or 0-100% by weight (meth)acrylate with C₂-C₂₂ alkyl chains, preferably 50-100% by weight methyl (meth)acrylate, and 0-50% by weight (meth)acrylate with C₂-C₂₂ alkyl chains.

In particular, the C₂-C₂₂ (meth)acrylic acid esters employed may be ethyl, n-propyl, i-propyl, n-butyl, i-butyl, sec-butyl, tert-butyl, pentyl, hexyl, heptyl, octyl, 2-ethylhexyl, 2-propyl heptyl, nonyl, decyl, stearyl, lauryl, octadecyl, heptadecyl, nonadecyl, eicosyl, henicosyl, docosyl, tricosyl, tetracosyl, pentacosyl, hexacosyl, heptacosyl, octacosyl, nonacosyl, triacontyl, behenyl methacrylate or acrylate, preferably n-butyl, 2-ethylhexyl, lauryl and stearyl, or mixtures of these monomers, most preferably lauryl.

Hydroxyl-, epoxy- and amino-functional methacrylates and acrylates may also be used.

As further comonomers, up to 50% by weight, preferably up to 20% by weight, of the following monomers, which are listed by way of example, can be employed: vinylaromatic compounds, such as styrene, alpha-methylstyrene, vinyltoluene or p-(tert-butyl) styrene; acrylic and methacrylic acid; acrylamide and methacrylamide; maleic acid and the imides and C₁-C₁₀-alkyl esters thereof; fumaric acid and the imides and C₁-C₁₀-alkyl esters thereof; itaconic acid and the imides and C₁-C₁₀-alkyl esters thereof; acrylonitrile and methacrylonitrile.

The acrylate and methacrylate homo or copolymers preferably have a weight average molecular weight M_{w} ranging from about 10 000 to about 800 000 g/mol. Typically, the weight average may range from about 20 000 g/mol to about 500 000 g/mol.

The molecular weight is determined by GPC using polystyrene standards (DIN 55672-1).

Polystyrene and Copolymers

Polystyrene and/or styrene copolymer can be prepared by all polymerization processes known to the person skilled in the art [cf. for example Ullmann's Encyclopedia, Sixth Edition, 2000 Electronic Release].

If appropriate, styrene copolymers may also be used; advantageously, these styrene copolymers comprise at least 50% by weight, preferably at least 80% by weight, of polystyrene incorporated in the form of polymerized units. Suitable comonomers are, for example, alpha-methylstyrene, styrenes halogenated on the nucleus, acrylonitrile, esters of acrylic or methacrylic acid with alcohols having 1 to 8 carbon atoms, N-vinylcarbazole, maleic acid (anhydride), (meth)acrylamide and/or vinyl acetate.

Advantageously, the polystyrene and/or styrene copolymer may comprise a small amount of a chain-branching agent incorporated in the form of polymerized units, i.e. a compound having more than one double bond, preferably two double bonds, such as divinylbenzene, butadiene and/or butanediol diacrylate. The branching agent is used in general in amounts of from 0.005 to 0.05 mol % based on styrene.

Styrene (co)polymers having a molecular weight in the range from 190 000 to 400 000 g/mol are preferably used. It is also possible to use mixtures of different styrene (co)polymers. Preferably used styrene polymers are crystal clear polystyrene (GPPS), high impact polystyrene, (HIPS), anionically polymerized polystyrene or high-impact polystyrene (A-IPS), styrene-u-methylstyrene copolymers, acrylonitrilebutadiene-styrene polymers (ABS), styrene-acrylonitrile (SAN), acrylonitrile-styrene-acrylate (ASA), methyl acrylate-butadiene-styrene (MBS), methyl methacrylate-acrylonitrile-butadiene-styrene (MARS) polymers or mixtures thereof or with polyphenylene ether (PPE).

Styropor, Neopor and/or Peripor from BASF SE is particularly preferably used as the polystyrene.

Thermoplastic Resin

When the twin-polymer composition of the present invention further contains a thermoplastic resin, the mechanical strength of the polymerized product may be further improved. Furthermore, in the case of using the composition in a form of adhesive film, the film molding capability can also be improved. Such a thermoplastic resin may be a phenoxy resin, a polyimide resin, a polyamideimide resin, a polyetherimide resin, a polysulfone resin, a polyethersulfone resin, a polyphenylene ether resin, a polycarbonate resin, a polyetherether ketone resin, and a polyester resin. These thermoplastic resins may be used alone or in combinations of two or more kinds thereof. The weight average molecular weight of the thermoplastic resin is preferably within a range of 5 000 to 200 000. When the weight average molecular weight is less than this range, the effects for improving the film molding capability and the mechanical strength are unlikely to be sufficiently exhibited. When the weight average molecular weight is more than this range, the compatibility with the cyanate ester resin and the naphthol-type epoxy resin is not sufficient, the surface irregularity after curing is increased, and the formation of a high-density fine wiring tends to be difficult. The weight average molecular weight in the present invention is measured by a gel permeation chromatography (GPC) method (in terms of polystyrene). Specifically, in the GPC method, the weight average molecular weight can be determined at a column temperature of 40° C. using LC-9A1RID-6A manufactured by Shimadzu Corporation as a measurement apparatus, Shodex K-800P/K-804L1 K-804L manufactured by Showa Denko K.K. as columns, and chloroform or the like as a mobile phase, and carrying out calculation using a calibration curve of standard polystyrene.

When the thermoplastic resin is mixed in the resin composition of the present invention, the content of the thermoplastic resin in the resin composition is not particularly limited, and is preferably 0.1 to 10% by weight, and more preferably from 1 to 5% by weight, relative to 100% by weight of non-volatile components in the resin composition. When the content of the thermoplastic resin is too small, the effects for improving the film molding capability and the mechanical strength are unlikely to be exhibited. When the content of the thermoplastic resin is too large, there is a tendency that the melt viscosity is increased and the arithmetic mean roughness of the surface of the insulating layer after the wet roughening step is increased.

Rubber Particle

When the composition of the present invention further contains a rubber particle, the plating peel strength may be improved, and effects for improving the drill processing properties, reducing the dielectric dissipation factor, and relieving the stress can be obtained. The rubber particle which can be used in the present invention is, for example, one that is insoluble in an organic solvent used for the preparation of a varnish of the composition and incompatible with the twin-monomer as the essential component. Therefore, the rubber particle may be resent in a dispersed state in the varnish of the composition of the present invention. In general, such a rubber particle may be prepared by increasing the molecular weight of the rubber component to such an extent that the rubber component is insoluble in the organic solvent, and converting it into a granular state.

Preferable examples of the rubber particle which can be used in the present invention may include a core-shell type rubber particle, a cross-linked acrylonitrile-butadiene rubber particle, a cross-linked styrene-butadiene rubber particle, and an acrylic rubber particle. The core-shell type rubber particle is a rubber particle having a core layer and a shell layer, and examples thereof may include a two-layer structure in which the shell layer as an external layer is made of a glassy polymer and the core layer as an internal layer is made of a rubbery polymer; and a three-layer structure in which the shell layer as an external layer is made of a glassy polymer, an interlayer is made of a rubbery polymer, and the core layer is made of a glassy polymer. The glassy polymer layer is made of, for example, a polymer of methyl methacrylate, and the rubbery polymer layer is made of, for example, a butyl acrylate polymer (butyl rubber). The rubber particle may be used in combinations of two or more kinds thereof. Specific examples of the core-shell type rubber particle may include Staphyloid AC3832, AC3816N, IM-401 Modified 1, and IM-401 Modified 7-17 (trade name, available from Ganz Chemical Co., Ltd.), and METABLEN KW-4426 (trade name, available from MITSUBISHI RAYON CO., LTD.). Specific examples of the crosslinked acrylonitrile butadiene rubber (NBR) particle may include XER-91 (average particle diameter: 0.5 micrometer, available from JSR Corporation). Specific examples of the crosslinked styrene butadiene rubber (SBR) particle may include XSK-500 (average particle diameter: 0.5 micrometer, available from JSR Corporation). Specific examples of the acrylic rubber particle may include METABLEN W300A (average particle diameter: 0.1 micrometer) and W450A (average particle diameter: 0.2 micrometer) (available from MITSUBISHI RAYON CO., LTD.).

An average particle diameter of the rubber particle to be mixed is preferably within a range of 0.005 to 1 micrometer, and more preferably within a range of 0.2 to 0.6 micrometer. The average particle diameter of the rubber particle used in the present invention can be measured by a dynamic light scattering method. For example, the measurement can be carried out by uniformly dispersing the rubber particles in an appropriate organic solvent by ultrasonic wave or the like, preparing the particle size distribution of the rubber particle using a concentrated system particle size analyzer (FPAR-1000, manufactured by Otsuka Electronics Co., Ltd.) on a mass basis, and defining its median diameter as the average particle diameter.

The content of the rubber particle is preferably 0.05 to 10% by weight, and more preferably 0.5 to 5% by weight, relative to 100% by weight of non-volatile components in the twin-monomer composition.

Flame Retardant

When the composition of the present invention further contains a flame retardant, flame retardancy can be imparted to the composition. Examples of the flame retardant may include an organic phosphorus-based flame retardant, an organic nitrogen-containing phosphorus compound, a nitrogen compound, a silicone-based flame retardant, and metal hydroxide. The organic phosphorus-based flame retardant may be a phenanthrene type phosphorus compound such as HCA, HCA-HQ, and HCA-NQ, available from SANKO CO., LTD., a phosphorus-containing benzoxazine compound such as HFB-2006M available from Showa High Polymer Co., Ltd., a phosphate ester compound such as REOFOS 30, 50, 65, 90, 110, TPP, RPD, BAPP, CPD, TCP, TXP, TBP, TOP, KP140, and TIBP, available from Ajinomoto Fine-Techno Co., Inc., TPPO and PPQ available from HOKKO CHEMICAL INDUSTRY CO., LTD., OP930 available from Clariant Ltd., and PX200 available from DAIHACHI CHEMICAL INDUSTRY CO., LTD. The organic nitrogen-containing phosphorus compound may be a phosphate ester amide compound such as SP670 and SP703, available from Shikoku Chemicals Corporation, and a phosphazene compound such as SPB100 and SPE100, available from Otsuka Chemical Co., Ltd. and FP-series available from FUSHIMI Pharmaceutical Co., Ltd. Metal hydroxide may be magnesium hydroxide such as UD65, UD650, and UD653, available from Ube Material Industries, Ltd., and aluminium hydroxide such as B-30, B-325, B-315, B-308, B-303, and UFH-20, available from Tomoe Engineering Co., Ltd.

The content of the flame retardant is preferably 0.5 to 10% by weight, and more preferably 1 to 5% by weight, relative to 100% by weight of non-volatile components in the composition.

Application

The application of the composition of the present invention is not particularly limited. The composition can be used over a wide range of application where a dielectric material is required, including an insulating sheet such as an adhesive film and a prepreg, a circuit substrate (applications for a laminate, a multilayered printed wiring board, etc.), a solder resist, an under fill material, a die bonding material, a semiconductor sealing material, a hole plugging material, and a module-embedding material. Among these, the composition of the present invention can be suitably used for forming an insulating layer in the manufacture of the multilayered printed wiring board (composition for an insulating layer of a multi-layered printed wiring board). Furthermore, the composition of the present invention can be suitably used as a composition for forming an insulating layer on which a conductive layer is formed by plating in the manufacture of the multi-layered printed wiring board (composition for an insulating layer of a multilayered printed wiring board on which a conductive layer is formed by plating). Although the composition of the present invention can be applied to a circuit substrate in a varnish state to form an insulating layer, it is industrially preferable, in general, to use the composition in a form of a sheet-shaped laminated material such as an adhesive film and a prepreg. From the viewpoint of lamination properties of the sheet-shaped laminated material, the softening point of the composition is preferably 40 to 150° C.

Due to the trend towards digital connectivity and 5G technology, special dielectric polymers with particularly low dielectric constant Dₖ and loss tangent D_{f} are needed to meet the 5G material specification focused on 5G applications. In particular, low dielectric constant and low loss polymers are required for but are not limited to:
antenna modules
personal computers
mobile telephones
electrical components and antenna substrates
electrothermal circuit (ETC).

Composite Material and Dielectric Film

A particular embodiment of the invention relates to the production of a composite material, also referred to as dielectric material, in particular a dielectric layer or film on a substrate. The terms “dielectric” and “insulating” are used herein synonymously. For this purpose, a thin layer of the composition as describe herein will be polymerized. This monomer film or layer is typically applied to the surface to be coated prior to the polymerization.

In a particular embodiment of the present invention the composite material essentially consists of, preferably consists of

(a) an inorganic phase,

(b) an organic polymer phase,

(c) optionally an inorganic filler,

(d) optionally a thermoplastic resin,

(e) optionally a rubber particle, and

(f) optionally a flame retardant.

The composition comprising the monomers of the formula M1 may be applied to the substrate in a manner known per se. In general, the composition will be applied to the surface of the substrate to be coated in viscous liquid form, for example as a liquid or melt or in the form of a solution in an inert diluent, preferably an aprotic organic solvent. The aprotic organic solvents include, in particular, hydrocarbons which may be aliphatic, cycloaliphatic or aromatic, and mixtures thereof with halogenated hydrocarbons.

Preferred solvents are hydrocarbons, for example acyclic hydrocarbons having generally 4 to 16 and preferably 3 to 8 carbon atoms, especially alkanes such as n-butane and isomers thereof, n-pentane and isomers thereof, n-hexane and isomers thereof, n-heptane and isomers thereof, and also n-octane, n-decane and isomers thereof, n-dodecane and isomers thereof, n-tetradecane and isomers thereof and n-hexadecane and isomers thereof, and additionally cycloalkanes having 5 to 16 carbon atoms, such as cyclopentane, methylcyclopentane, cyclo-hexane, methylcyclohexane, cycloheptane, cyclooctane, decalin, cyclododecane, biscyclo-hexylmethane, aromatic hydrocarbons such as benzene, toluene, xylenes, mesitylene, ethylbenzene, cumene (2-propylbenzene), isocumene (1-propylbenzene), tert-butylbenzene, isopropylnaphthalene or diisopropylnaphthalene.

Preference is also given to mixtures of the aforementioned hydrocarbons with halogenated hydrocarbons, such as halogenated aliphatic hydrocarbons, for example such as chloromethane, dichloromethane, trichloromethane, chloroethane, 1,2-dichloroethane and 1, 1, 1-trichloroethane and 1-chlorobutane, and also halogenated aromatic hydrocarbons such as chlorobenzene, 1,2-dichlorobenzene and fluorobenzene.

The most preferred solvents are oxygen containing solvents from the group ethers, such as dioxane, tetrahydrofuran, diisopropyl ether, 1-methoxy-2-(2-methoxyethoxy)ethane (diglyme), anizol or from the group of esters such as ethyl acetate, butyl acetate, dimethycarbonate or from the group of ketons such as methyl ethyl keton, aceton, buthanone.

Preferably, the proportion of the monomer in the mixtures is at least 50% by volume, particularly at least 80% by volume and especially at least 90% by volume.

In a preferred embodiment of the invention, the organic solvent used for applying the film comprises at least one aromatic hydrocarbon, especially at least one alkylaromatic, in particular mono-, di- or trialkylbenzenes and mono-, di- or trialkylnaphthalenes, e.g. toluene, xylene and xylene mixtures, 1,2,4-trimethylbenzene, mesitylene, ethylbenzene, cumene, isocumene, tert-butylbenzene, isopropylnaphthalene or diisopropylnaphthalene, and mixtures of these solvents.

The organic solvents may be used in combination of two or more kinds thereof.

When the composition is applied to the surface to be coated in the form of a solution, the diluent will preferably be removed prior to the polymerization. The diluent is therefore preferably a volatile organic solvent which has a boiling point at standard pressure preferably does not exceed 120° C. and is especially in the range from 40 to 120° C. Examples of particularly suitable organic solvents for this purpose are aromatic hydrocarbon, such as but not limited to toluene, ketons such as but not limited to methyl ethyl ketone, and ethers such as but not limited to diglyme.

The homo- or copolymerization of the composition is preferably conducted in bulk, i.e. in a melt of the monomers of the formula M1, in which case the melt may optionally comprise up to 20% by weight and especially up to 10% by weight of an inert diluent.

Preference is given to performing the polymerization of the composition in the substantial absence of water, which means that the concentration of water at the start of the polymerization is less than 0.1% by weight. Accordingly, preferred compositions comprise monomers which do not release any water under polymerization conditions.

Although a drying condition is not particularly limited, it is performed so that the content of the organic solvent in the composition layer is 10% by weight or less, and preferably 5% by weight or less. The drying condition varies depending upon the content of the organic solvent in the varnish and the boiling point of the organic solvent. For example, the composition layer can be formed by drying the varnish containing 30 to 60% by weight of the organic solvent at 50 to 1500 C. for about 3 to 10 minutes.

The homo- or copolymerization of the monomers is usually performed at elevated temperature. The temperature needed for polymerization depends on the stability of the composition, which is determined crucially by the type of metal or semimetal M and the used organic derivate. The temperature required for the polymerization of the particular monomer can be determined by the person skilled in the art by routine experiments. The temperature required for the polymerization will generally be at least 60° C., particularly at least 80° C. and especially at least 100° C. or at least 120° C. It will preferably not exceed 350° C., particularly 300° C. and especially 250° C. The temperature needed for polymerization is generally above 120° C., particularly above 140° C. and it is performed preferably at temperatures in the range from 140 to 200° C. and especially at temperatures in the range from 160 to 180° C.

The dimensions of the phase domains in the dielectric materials or films obtained by polymerization of the subject twin monomers are generally less than 200 nm and are frequently in the region of a few nanometers, for example not more than 50 nm or not more than 20 nm or not more than 10 nm or not more than 5 nm. In addition, the phase domains of the inorganic or organometallic phase and the phase domains of the organic phase typically have a co-continuous arrangement, i.e. both the organic phase and the inorganic or organometallic phase penetrate one another and essentially do not form any discontinuous regions. The distances between adjacent phase boundaries, or the distances between the domains of adjacent identical phases, are extremely small and are generally on average not more than 200 nm, frequently on average not more than 50 nm or 20 nm and especially on average not more than 10 nm, or not more than 5 nm. There is typically no occurrence of macroscopically visible separation into discontinuous domains of the particular phase in such processes. The advantages of these small phase domains are a better electrical performance as well as a better compatibility and adherence to an inorganic filler, particularly silica. In contrast the traditional epoxy systems have phase domains in the micrometer range or even higher.

In the dielectric film, the thickness of the formed dielectric layer is preferably equal to or more than the thickness of the conductive layer. Since the thickness of the conductive layer in the circuit substrate is generally within a range of 5 to 70 micrometer, the dielectric layer preferably has a thickness of 10 to 100 micrometer.

Examples of the support may include various plastic films including a film of polyolefin such as polyethylene, polypropylene and polyvinyl chloride, a film of polyester such as polyethylene terephthalate (hereinafter may be abbreviated as “PET”) and polyethylene naphthalate, a polycarbonate film, and a polyimide film. Further, a release paper, a metal foil such as a copper foil and an aluminum foil, and the like, can be used. The support and a protective film to be described later may be subjected to a surface treatment such as a mat treatment and a corona treatment. Alternatively, the support and the protective film may be subjected to a release treatment with a release agent such as a silicone resin-based release agent, an alkyd resin-based release agent, and a fluororesin-based release agent.

Although the thickness of the support is not particularly limited, it is preferably 10 to 150 micrometer, and more preferably 25 to 50 micrometer.

On the surface of the twin-polymer composition layer with which the support is not in contact, a protective film corresponding to the support can be further laminated. The thickness of the protective film is not particularly limited and is, for example, 1 to 40 micrometer. When the protective film is laminated, attachment of dusts or the like or generation of scratch on the surface of the dielectric film can be prevented. The dielectric film can be wound in a roll form and stored.

Multilayered Printed Wiring Board Using Adhesive Film.

Next, an example of a method for manufacturing a multilayered printed wiring board using thus manufactured dielectric layer or film will be described.

Firstly, the adhesive film is laminated on one surface or both surfaces of a circuit substrate using a vacuum laminator. Examples of the substrate used for the circuit substrate may include a glass epoxy substrate, a metal substrate, a polyester substrate, a polyimide substrate, a BT resin substrate, and a thermosetting polyphenylene ether substrate. The circuit substrate used herein refers to a substrate having a patterned conductive layer (circuit) formed on one surface or both surfaces thereof. Further, a multilayered printed wiring board that has alternately layered conductive and insulating layers, and that has a patterned conductive layer (circuit) on one surface or both surfaces of an outermost layer thereof, is also included in the circuit substrate used herein. The surface of the conductive layer may be previously subjected to a roughening treatment such as a blackening treatment and copper etching. In the laminating, when the adhesive film has a protective film, the protective film is first removed, then the adhesive film and the circuit substrate are preheated, if desired, and the adhesive film is compression-bonded to the circuit substrate while pressing and heating. In the adhesive film of the present invention, there is suitably adopted a method in which the adhesive film is laminated on the circuit substrate under reduced pressure by a vacuum lamination method. Although a lamination condition is not particularly limited, it is preferable, for example, that the lamination is carried out under the following condition: A compression bonding temperature (lamination temperature) of preferably 70 to 140° C.; a compression bonding pressure of preferably 1 to 11 kgf/cm² (9.8×104 to 107.9×104 N/m²); and under a reduced pressure of 20 mmHg (26.7 hPa) or less in terms of a pneumatic pressure. The lamination method may be a method of batch mode or of continuous mode using rolls. The vacuum lamination can be performed using a commercially available vacuum laminator. Examples of the commercially available vacuum laminator may include a vacuum applicator manufactured by Nichigo-Morton Co., Ltd., a vacuum pressure laminator manufactured by Meiki Co., Ltd., a roll type dry coater manufactured by Hitachi Industries Co., Ltd., and a vacuum laminator manufactured by Hitachi AIC Inc.

The lamination step of performing heating and pressing under reduced pressure can be carried out using a general vacuum hot press machine. For example, the lamination step can be carried out by pressing a metal plate such as a heated SUS plate from a support layer side. As to a pressing condition, a degree of reduced pressure is usually 1×10⁻² MPa or less, and preferably 1×10⁻³ MPa or less. Although the heating and pressing can be performed by one stage, it is preferable to perform the heating and pressing separately by two or more stages from the viewpoint of controlling bleeding of the twin polymer. For example, it is preferable to perform the first-stage pressing at a temperature of 70 to 150° C. under a pressure of 1 to 15 kgf/cm² and the second-stage pressing at a temperature of 150 to 200° C. under a pressure of 1 to 40 kgf/cm². It is preferable that the pressing is performed at each stage for a period of 30 to 120 minutes. Examples of a commercially available vacuum hot pressing machine may include MNPC-V-750-5-200 (manufactured by Meiki Co., Ltd.) and VHI-1603 (manufactured by KITAGAWA SEIKI CO., LTD.).

The insulating layer can be formed on the circuit substrate by laminating the adhesive film on the circuit substrate, cooling the laminate to about room temperature, releasing the support in the case of releasing the support.

Thereafter, the insulating layer formed on the circuit substrate is perforated as necessary to form a via hole or a through-hole. The perforation can be performed, for example, by a known method using drill, laser, plasma, or the like, or can be performed through a combination of these methods, if necessary. The perforation using a laser such as a carbon dioxide gas laser and a Nd:YAG laser is the most common method.

Subsequently, the conductive layer is formed on the insulating layer by dry plating or wet plating. As the dry plating, there can be used a known method such as vapor deposition, sputtering, and ion plating. In the wet plating, the surface of the insulating layer is subjected to a swelling treatment with a swelling solution, a roughening treatment with an oxidant, and a neutralization treatment with a neutralization solution, in this order, to form convex-concave anchor. The swelling treatment with a swelling solution can be performed by immersing the insulating layer into the swelling solution at 50 to 80° C. for 5 to 20 minutes. Examples of the swelling solution may include an alkali solution and a surfactant solution. An alkali solution is preferable. Examples of the alkali solution may include a sodium hydroxide solution and a potassium hydroxide solution. Examples of a commercially available swelling solution may include Swelling Dip Securiganth P and Swelling Dip Securiganth SBU, available from Atotech. The roughening treatment with an oxidant can be performed by immersing the insulating layer into an oxidant solution at 60° C. to 80° C. for 10 minutes to 30 minutes. Examples of the oxidant may include an alkaline permanganate solution in which potassium permanganate or sodium permanganate is dissolved in an aqueous solution of sodium hydroxide, dichromate, ozone, hydrogen peroxide/sulfuric acid, and nitric acid. The concentration of permanganate in an alkaline permanganate solution is preferably 5 to 10% by weight. Examples of a commercially available oxidant may include an alkaline permanganate solution such as Concentrate Compact CP and Dosing Solution Securiganth P available from Atotech. The neutralization treatment with a neutralization solution can be performed by immersing the insulating layer into the neutralization solution at 30 to 50° C. for 3 to 10 minutes. The neutralization solution is preferably an acidic aqueous solution. Examples of a commercially available neutralization solution may include Reduction Solution Securiganth P available from Atotech.

Subsequently, the conductive layer is formed by combination of electro less plating and electrolytic plating. The conductive layer can also be formed by forming a plating resist with a reverse pattern of the conductive layer and performing only electro less plating. As a subsequent patterning method, there can be used a subtractive method or a semiadditive method which is known to those skilled in the art.

Prepreg

The prepreg of the present invention may be manufactured by impregnating the twin polymer composition of the present invention in a sheet-shaped reinforcing base material made of fiber using a hot melt method or a solvent method and then semi-curing the resultant by heating. That is, the prepreg can be formed so that the composition of the present invention is impregnated in a sheet-shaped reinforcing base material made of fiber. As the sheet-shaped reinforcing base material made of fiber, there can be used, for example, those made of fiber that is commonly used for a prepreg, such as a glass cloth and an aramid fiber.

The holt melt method is a method for manufacturing a prepreg by once applying a twin-monomer composition to a coated paper, which has good release properties against the composition, without dissolving the twin-monomer composition in an organic solvent and laminating it onto a sheet-shaped reinforcing base material, or by applying a twin-monomer composition directly to a sheet-shaped reinforcing base material using a die coater without dissolving the twin-monomer composition in an organic solvent. The solvent method is a method in which a twin-monomer composition is dissolved in an organic solvent to prepare a twin-monomer composition varnish similarly to the case of manufacturing the adhesive film, and a sheet-shaped reinforcing base material is immersed in this varnish, thereby impregnating the twin-monomer composition varnish in the sheet-shaped reinforcing base material, and then the resultant is dried.

Multilayered Printed Wring Board Using Prepreg

Next, an example of a method for manufacturing a multilayered printed wiring board using the prepreg thus manufactured will be described. One sheet or optionally a plurality of sheets of the prepreg of the present invention are stacked on the circuit substrate and sandwiched by metal plates via a release film, followed by vacuum press lamination under a pressing and heating condition. The pressing and heating condition is preferably under a pressure of 5 to 40 kgf/cm2 (49×104 to 392×104 N/m2), at a temperature of 120 to 200° C., and for a period of 20 to 100 minutes. It is also possible to laminate the prepreg onto the circuit substrate by a vacuum lamination method and then to perform thermal curing similarly to the case of using the adhesive film. Thereafter, the multilayered printed wiring board can be manufactured by roughening a surface of the polymerized prepreg and then forming a conductive layer by plating in the same manner as described above.

Semiconductor Device

A semiconductor device can be manufactured using the multilayered printed wiring board of the present invention. A semiconductor device can be manufactured by mounting a semiconductor chip on conducting parts of the multi-layered printed wiring board of the present invention. The “conducting part” means a “part for conducting electric signals in the multilayered printed wiring board,” which may be positioned on the surface or embedded parts therein. The semiconductor chip is not particularly limited as long as the chip is an electric circuit element made of a semiconductor material.

The method for mounting a semiconductor chip in manufacturing the semiconductor device of the present invention is not particularly limited as long as the semiconductor chip effectively functions. Specific examples thereof may include a wire bonding mounting method, a flip-chip mounting method, a mounting method using a bump less build-up layer (BBUL), a mounting method using an anisotropic conductive film (ACF), and a mounting method using a non-conductive film (NCF).

The “mounting method using a bumpless build-up layer (BBUL)” means “a mounting method in which a semiconductor chip is directly embedded in a concave of a multi-layered printed wiring board, followed by connecting the semiconductor chip to the wiring on the printed wiring board.” Further, the mounting method is roughly classified into the following BBUL method 1) and BBUL method 2).

BBUL method 1): Method for mounting a semiconductor chip in a concave of a multilayered printed wiring board with an underfilling agent

BBUL method 2): Method for mounting a semiconductor chip in a concave of a multilayered printed wiring board with an adhesive film or a prepreg

The BBUL method 1) specifically includes the following steps:
Step 1) The conductive layers are removed from both sides of a multilayered printed wiring board, and through-holes are formed with a laser or a mechanical drill in the multilayered printed wiring board.
Step 2) An adhesive tape is stuck to one side of the multilayered printed wiring board, and the base of the semiconductor chip is disposed in the through-hole so that the semiconductor chip is fixed on the adhesive tape. At that time, it is preferable that the semiconductor chip is disposed at a position lower than the height of the through-hole.
Step 3) An underfilling agent is injected and loaded into a space between the through-hole and the semiconductor chip to fix the semiconductor chip in the through-hole.
Step 4) After that, the adhesive tape is peeled off to expose the base of the semiconductor chip.
Step 5) On the base side of the semiconductor chip, the adhesive film or prepreg of the present invention is laminated to cover the semiconductor chip.
Step 6) The adhesive film or prepreg is then perforated by a laser to expose a bonding pad on the base of the semiconductor chip, followed by the roughening treatment, electroless plating and electrolytic plating as described above, to connect the wiring. If necessary, the adhesive film or prepreg may be further laminated.

The BBUL method 2) specifically includes the following steps:
Step 1) Photoresist films are formed on conductive layers on both sides of a multilayered printed wiring board, and apertures are formed only on one side of the photoresist films by a photolithography process.
Step 2) The conductive layer exposed in the apertures is removed using an etching solution to expose an insulating layer, and the resist films on both sides are then removed.
Step 3) All of the exposed insulting layers are removed and perforation is performed with a laser or drill to form concaves. It is preferable to use a laser in which the laser energy can be adjusted so that laser absorption in copper is decreased and laser absorption in the insulating layer is increased, and more preferable to use a carbon dioxide gas laser. The use of such a laser allows removing only the insulating layer without penetrating the conductive layer on the opposite side of the aperture of the conductive layer.
Step 4) The semiconductor chip is disposed at the concave so that the base of the semiconductor chip faces the aperture side, and the adhesive film or prepreg of the present invention is laminated from the aperture side to cover the semiconductor chip and embedded in a space between the semiconductor chip and the concave. It is preferable that the semiconductor chip is disposed at a position lower than the height of the concave.
Step 5) The adhesive film or prepreg is then perforated with a laser to expose a bonding pad on the base of the semiconductor chip.
Step 6) The roughening treatment, non-electrolytic plating, and electrolytic plating as described above, are performed to connect the wiring, and if necessary, an adhesive film or prepreg may further be laminated.

Among the methods for mounting a semiconductor chip, from the viewpoints of downsizing of a semiconductor device and a reduction of transmission loss or from the viewpoints of no influence of thermal history on the semiconductor chip because of using no solder and no strain to be occurred in the future between the dielectric material and the solder, the mounting method using a bump less build-up layer (BBUL) is preferable, the BBUL methods 1) and 2) are more preferable, and the BBUL method 2) is still more preferable.

Other features of the invention will become apparent in the course of the following descriptions of exemplary embodiments which are given for illustration of the invention and are not intended to be limiting thereof.

All percent, ppm or comparable values refer to the weight with respect to the total weight of the respective composition except where otherwise indicated. All cited documents are incorporated herein by reference.

The following examples shall further illustrate the present invention without restricting the scope of the invention.

### EXAMPLES

Measurement and Evaluation of Dielectric Permittivity and Loss Tangent

The thickness of the films was measured with a micrometer gauge (product of Mitutoyo, Japan, 0.001-5 mm). The dielectric measurements were done with a split post dielectric resonator (SPDR) (product of QWED, Poland) at 10 GHz and a vectorial network analyzer E5071C (product of keysight Technologies).

SPDR operated at the TE01δ mode that restricts the electric field component to the azimuthal direction of the film sample (F.Chen et al, Journal of Electromagnetic Analysis and Applications 4 (2012), 358-361). The resonance mode is insensitive to air gaps perpendicular to the film sample.

The dielectric permittivity Dₖ (also often referred to as dielectric constant) was determined from the resonance frequency shift due to the sample insertion. The typical uncertainty of the permittivity is better than ±1% since the thickness of a sample under test is measured with an accuracy of ±0.7% or better.

The loss tangent D_{f} can be determined from the Q factors of the empty cavity and the cavity with the sample, respectively, via formula tan δ=1/Q. The typical loss tangent resolution was 2·10⁻⁵.

### Example A1: Synthesis of tetra-(4-methoxybenzyloxy) silane

108 g 4-methoxybenzylalcohol was dissolved in 500 ml toluene in 1 l 3-neck flask equipped with mechanic stirrer under nitrogen. 82.1 g 1-methyl imidazole is added and 42.5 g silicon tetrachloride was added slowly in 1 h. The exothermic reaction was kept below 50° C. The mixture was then heated under continuous stirring at 100° C. for 5 h.

The stirring was stopped, and the mixture was let cool down to room temperature. The formed imidazolium salt was filtered, and the solution concentrated at 100° C. and 5 mbar. 112 g product was obtained. 1H-NMR (CD₂Cl₂): 3.76 ppm (s, 12H), 4.70 ppm (s, 8H), 6.83 ppm (d, 8H), 7.20 ppm (d, 8H).

### Example A2: Synthesis of di-(4-methoxybenzyloxy)dimethyl silane

69.1 g 4-methoxybenzylalcohol was dissolved in 400 ml toluene in 1 l 3-neck flask equipped with mechanic stirrer under nitrogen. 41 g 1-methyl imidazole was added and 32.3 g dichloro-dimethylsilane was added slowly at 40° C. in 1 h. During the addition the temperature raised to 50° C. The mixture was then heated to 60° C. under continuous stirring 0.5 h, then at 85° C. for another 2 h.

The stirring was stopped, and the mixture was let cool down to room temperature. The formed imidazolium salt was filtered, and the solution concentrated at 90° C. and 10 mbar. 78 g product was obtained. 1H-NMR (CD₂Cl₂): 0.16 ppm (s, 6H), 3.77 ppm (s, 6H), 4.66 ppm (s, 4H), 6.85 ppm (d, 4H), 7.22 ppm (d, 4H).

### Example 1: Polymerization and Making of Film with silica and Acid Evaporation

1 g di-4-methoxybenzyloxy dimethylsilane and 2 g tetra-4-methoxybenzyloxysilane were mixed together. 0.8 g of the mixture was added to 1.2 g unfunctionalized silica particles with an average size of 0.5 μm with round shape (SE203-SXJ from Admatec). For better homogeneity 1 ml toluene was added and the mixture further homogenized in ultrasound bath.

The mixture was then applied with a 200 μm coating knife on a PET foil. 1 g methanesulfonic acid is applied in a 1-cm stripe next to the PET foil and both materials were covered with a plastic container and heated to 80° C. for 5 h. A white, matt, solid film formed. The PET foil with the monomers were then placed in an oven and heated at 180° C. for 3 h. A brown, brittle film formed.

The electric properties of the film were measured: Average thickness of 3 cuts from the film: 82 μm, Dₖ value: 2.75, D_{f} value: 0.0062.

### Example B2: Polymerization and Making of Film with Acid Solution and without silica

2.5 g of a 10% solution of polymethylmethacrylate (with a Mw of 500 000 g/mol and size of 140 mesh purchased from Alfa Aesar) in methylethylketone and 0.33 g di-4-methoxybenzyloxy dimethylsilane and 0.67 g tetra-4-methoxybenzyloxysilane prepared in examples A1 and A2 were mixed together. 6 drops of a 5% solution of methansulfonic acid in methylethylketone was added. The mixture was homogenized in ultrasound bath and then applied with a 300 μm coating knife on a PET foil. The foil covered with a plastic container and heated to 80° C. for 5 h. A white, solid film formed. The PET foil with the monomers were then placed in an oven and heated at 160° C. for 5 h. A colorless film formed.

The electric properties of the film were measured:

Average thickness of 3 cuts from the film: 13 μm, Dₖ value: 2.5, D value: 0.0183.

### Example B3: Polymerization and Making of Film with Acid Evaporation with silica

2.5 g of a 10% solution of polymethylmethacrylate in methylethylketone and 0.33 g di-4-methoxybenzyloxy dimethylsilane, 0.67 g tetra-4-methoxybenzyloxysilane prepared in examples A1 and A2, and 1.88 g silica functionalized with methacryl-groups (SFP-20M from Denka) were mixed together. The mixture was homogenized in ultrasound bath and then applied with a 300 μm coating knife on a PET foil. 1 g methansulfonic acid was applied in a 1-cm stripe next to the PET foil and both materials were covered with a plastic container and heated to 80° C. for 5 h. A white, solid film formed. The PET foil with the monomers were then placed in an oven and heated at 160° C. for 5 h. A colorless film formed.

The electric properties of the film were measured:

Average thickness of 3 cuts from the film: 57 μm, Dₖ value: 1.91, D_{f} value: 0.0054.

### Example B4: Polymerization and Making of Film with silica and Acid Solution

2.5 g wt 10% solution of polymethylmethacrylate in bis(2-methoxyethyl)ether (diglyme), 0.33 g di-4-methoxybenzyloxy dimethylsilane, 0.67 g tetra-4-methoxybenzyloxysilane prepared in examples A1 and A2, and 1.25 g silica (SE203-SXJ from Admatec) were mixed together. 6 drops of 5% solution of methansulfonic acid in methylethylketone was added. The mixture was homogenized in ultrasound bath and then applied with a 400 μm coating knife on a PET foil. The foil was covered with a plastic container and heated to 80° C. for 5 h. A white, solid film formed. The PET foil with the monomers were then placed in an oven and heated at 160° C. for 5 h. A colorless film formed.

Variations of binders, concentrations, and monomer compositions are summarized in table 1:

TABLE 1

| | | | | film | | |
|---|---|---|---|---|---|---|
| | TMBS/DMBS | | | thickness | | |
| Ex. | mol ratio | Binder | Silica | [μm] | D_{f} | Dₖ |
| B4.1 | 2:1 | 30% PMMA | 60% | 48 | 0.0046 | 2.47 |
| B4.2 | 2:1 | 30% PMMA | 60% | 58 | 0.0046 | 2.64 |
| B4.3 | 2:1 | 30% PMMA | 60% | 54 | 0.0045 | 2.58 |
| B4.4 | 2:1 | 30% PMMA | 60% | 49 | 0.0046 | 2.71 |
| B4.5 | 2:1 | 30% PMMA | 60% | 48 | 0.0043 | 2.48 |
| B4.6 | 2:1 | 30% PMMA | 60% | 48 | 0.0044 | 2.48 |
| B4.7 | 2:1 | 30% PMMA | 60% | 50 | 0.0044 | 2.46 |
| B4.8 | 2:1 | 30% PMMA | 60% | 42 | 0.0043 | 2.51 |
| B4.9 | 2:1 | 30% PMMA | 65% | 45 | 0.0043 | 2.64 |
| B4.10 | 2:1 | 30% PMMA | 70% | 57 | 0.0040 | 2.63 |
| B4.11 | 1:1 | 30% PMMA | 60% | 49 | 0.0045 | 2.51 |
| B4.12 | 1:2 | 30% PMMA | 60% | 48 | 0.0047 | 2.61 |
| B4.13 | 1:3 | 30% PMMA | 60% | 47 | 0.0046 | 2.40 |
| B4.14 | 1:4 | 30% PMMA | 60% | 37 | 0.0044 | 2.51 |
| B4.15 | 1:4 | 30% PMMA | 70% | 56 | 0.0033 | 2.51 |
| B4.16 | 2:1 | 20% PS158K | 60% | 45 | 0.0041 | 2.36 |
| B4.17 | 2:1 | 30% PS158K | 60% | 36 | 0.0036 | 2.51 |
| B4.18 | 2:1 | 30% PS158K | 70% | 53 | 0.0033 | 2.54 |
| B4.19 | 1:2 | 30% PS158K | 60% | 40 | 0.0029 | 2.24 |
| B4.20 | 1:2 | 30% PS158K | 60% | 53 | 0.0031 | 2.46 |
| B4.21 | 1:2 | 30% PS158K | 70% | 51 | 0.0028 | 2.68 |
| B4.22 | 1:2 | 40% PS158K | 70% | 55 | 0.0026 | 2.63 |
| B4.23 | 1:2 | 40% PS158K | 70% | 48 | 0.0022 | 2.60 |
| B4.24 | 1:4 | 30% PS158K | 70% | 51 | 0.0020 | 2.56 |
| B4.25 | 1:4 | 40% PS158K | 70% | 48 | 0.0021 | 2.78 |
| B4.26 | only TMBS | 30% PMMA | 60% | 100 | 0.0125 | 3.15 |
| B4.27 | only 2-TMBS | 30% PMMA | 60% | 77 | 0.0057 | 2.96 |

Abreviations: tetra-4-methoxybenzyloxysilane: TMBS; methoxybenzyloxy dimethylsilane: DMBS; tetra-2-methoxybenzyloxysilane: 2-TMBS; polymethylmethacryate: PMMA; polystyrene: PS158K.

### Comparative Example E5: Polymerization and Making of Film from a Mixture of Spiro and Half-Spiro Compounds

1 g solid 2,2′-spiro-bi[4H-1,3,2-benzodioxasilin] and 1 g liquid 2-spiro[4H-1,3,2-benzodioxa-dimethylsilin] were mixed together at room temperature and 10 mg methane sulfonic acid in 0.1 g anizol was added. The mixture was applied with a 200 μm coating knife on a PET foil. The produced film is inhomogeneous and small particles formed. The PET foil with the monomers were then placed in an oven and heated at 150° C. for 5 h. An inhomogeneous red film formed. Same results were obtained with 1 to 2 g and 1 to 3 g monomer ratios.

Because of the inhomogeneity the electric properties were not measured.

It needs to be noted that experiments made without anizol lead to even worse results.

### Comparative Example B6: Polymerization and Making of Film from a Mixture of tetraphenoxy silane and trioxane

1 g tetraphenoxysilane and 0.3 g trioxane were mixed together for 10 min at room temperature. 13 mg methansulfonic acid in 0.13 g anizol was added. The mixture was applied with a 200 μm coating knife on a PET foil. The produced film is inhomogeneous and hazy. The PET foil with the monomers were then placed in an oven and heated at 150° C. for 5 h. An inhomogeneous white film formed.

Because of the inhomogeneity the electric properties were not measured.

Comparative Example B7: Polymerization and Making of Film from a Mixture of tetrafurfuryloxysilane

The liquid 1 g tetrafurfuryloxysilane was applied without solvent with a 200 μm coating knife on a PET foil. 1 g methansulfonic acid is applied in a 1-cm stripe next to the PET foil and both materials were covered with a plastic container and heated to 80° for 5 h. Both the plastic container and the film became black, but film did not form.

TABLE 2

| | | homogenous | | | | |
|---|---|---|---|---|---|---|
| Ex. | Silane | film formed | Binder | Filler | Df | Dk |
| B1 | di-4-methoxybenzyloxy dimethyl + | + | — | SiO₂ | 0.0062 | 2.75 |
| | tetra-4-methoxybenzyloxy (1:2) | | | | | |
| B2 | di-4-methoxybenzyloxy dimethyl + | + | PMMA | — | 0.0183 | 2.50 |
| | tetra-4-methoxybenzyloxy (1:2) | | | | | |
| B3 | di-4-methoxybenzyloxy dimethyl + | + | PMMA | SiO₂ | 0.0054 | 1.91 |
| | tetra-4-methoxybenzyloxy (1:2) | | | | | |
| B5 | Spiro + Half-Spiro oxysilane | − | — | — | n/a- | n/a- |
| (comp) | | | | | | |
| B6 | tetraphenoxy silane | − | — | — | n/a | n/a |
| (comp) | | | | | | |
| B7 | tetrafurfuryloxysilane | − | — | — | n/a | n/a |
| (comp) | | | | | | |

Table 2 shows that, in contrast to the alkoxyaryloxy silane twin monomers according to the present invention, proper twin polymer films are not formed by using the prior art bidentate siline twin monomers or phenoxy silane twin monomers.

1.-15. (canceled)

16. A composition comprising a twin monomer of the general formula M1 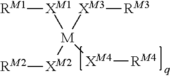
wherein
M is a metal or semimetal of main group 3 or 4 of the periodic table;
X^{M1}, X^{M2} are each O;
R^{M1}, R^{M2} are the same or different and are each an —CR^{a}R^{b}—Ar—O—R^{c};
Ar is a C₆ to C₃₀ carbocyclic ring system;
R^{a}, R^{b} are the same or different and are each H or C₁ to C₆ alkyl;
R^{c} is C₁-C₂₂-alkyl, benzyl or phenyl;
q according to the valency and charge of M is 0 or 1;
X^{M3}, X^{M4} are the same or different and are each O, C₆ to C₁₀ aryl, or —CH₂—;
R^{M3}, R^{M4} are the same or different and are each R^{M1}, H, C₁-C₂₂ alkyl, or a polymer selected from a polyalkylene, a polysiloxane, or a polyether.

17. The composition according to claim 16, wherein M is B, Al, Si, Ti or Zr.

18. The composition according to claim 16, wherein X^{M3} and X^{M4} are the same or different and are each O, phenyl or naphthyl, or —CH2-.

19. The composition according to claim 16, wherein R^{M3}, R^{M4} are the same or different and are each O, C₁-C₁₂ alkyl, or a polymer selected from a polysiloxane or a polyether.

20. The composition according to claim 16, wherein Ar is phenyl and R^{c} is C₁-C₁₂-alkoxy, benzyloxy or phenoxy;

21. The composition according to claim 16, wherein R^{a} and R^{b} are the same or different and are each H or C₁ to C₄ alkyl, preferably H.

22. The composition according to claim 16, wherein the twin monomer has the general formula M2 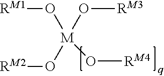
wherein
M is a metal or semimetal, generally a metal or semimetal of main group 3 or 4 or of transition group 4 of the periodic table;
R^{M1}, R^{M2} are each an —CR^{a}R^{b}—Ar;
Ar is a C₆ to C₁₂ aromatic ring and particularly a phenyl ring, where Ar comprises 1 or 2 substituents, selected from C₁-C₄-alkoxy;
R^{a}, R^{b} are the same or different and are each H or C₁ to C₄ alkyl.
q according to the valency and charge of M is 0 or 1;
R^{M3}, R^{M4} are each R^{M1}.

23. The composition according to claim 16, wherein the twin monomer has the general formula M2a 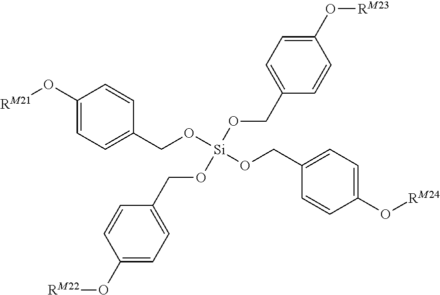
or M2a′ 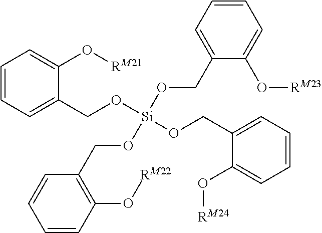
wherein R^{M21}, R^{M22}, R^{M23}, and R^{M24} are each independently selected from methyl, ethyl, propyl or butyl.

24. The composition according to claim 16, wherein the twin monomer has the general formula M2 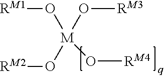
wherein
M is a metal or semimetal, generally a metal or semimetal of main group 3 or 4 or of transition group 4 of the periodic table;
R^{M1}, R^{M2} are each an —CR^{a}R^{b}—Ar;
Ar is a C₆ to C₁₂ aromatic ring and particularly a phenyl ring, where Ar comprises 1 or 2 substituents, preferably 1 substituent, selected from C₁-C₄-alkoxy;
R^{a}, R^{b} are the same or different and are each H or C₁ to C₄ alkyl.
q according to the valency and charge of M is 0 or 1;
R^{M3}, R^{M4} are the same or different and are each H, C₁-C₂₂ alkyl, or a polymer.

25. The composition according to claim 16, wherein the twin monomer has the general formula M2b 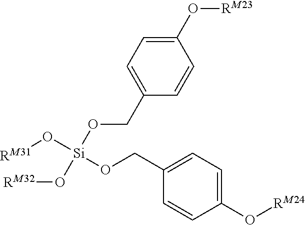
or M2b′ 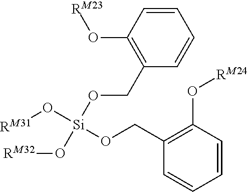
wherein R^{M31}, R^{M32}, R^{M23}, and R^{M24} are each independently selected from methyl, ethyl, propyl or butyl.

26. The composition according to claim 16, further comprising an inorganic filler, a polymeric binder, or a combination thereof.

27. Use of a composition according to claim 16 for depositing a dielectric material, particularly a dielectric film, on a circuit substrate, particularly for manufacturing a printed wiring board.

28. A dielectric film prepared by polymerizing a composition according to claim 16 in the presence of an acidic catalyst at temperature of preferably from 60° C. to 200° C., wherein the dielectric layer has a dielectric resistance Dₖ of 3 or below and a loss tangent D_{f} of 0.02 or below.

29. A dielectric film according to claim 28, received by polymerizing the twin monomer according to claim 23 and the twin monomer according to claim 25 in a mixing ratio of from 10:90 to 90:10 by weight.

30. A multi-layered printed wiring board comprising a dielectric film according to claim 28.
